(19) United States
(12) Patent Application Publication
(10) Pub. No.: US 2021/0189792 A1
(43) Pub. Date: Jun. 24, 2021

(54) FUNCTIONAL ELEMENT HAVING ELECTRICALLY CONTROLLABLE OPTICAL PROPERTIES

(71) Applicant: SAINT-GOBAIN GLASS FRANCE, Courbevoie (FR)

(72) Inventors: Marcel KLEIN, Baesweiler (DE); Alicia DRÖGE, Aachen (DE)

(21) Appl. No.: 16/757,220

(22) PCT Filed: Oct. 18, 2018
(86) PCT No.: PCT/EP2018/078471

§ 371 Date: Apr. 17, 2020

(30) Foreign Application Priority Data
Oct. 20, 2017 (EP) 17197483.5

(51) Int. Cl. E06B 3/67; G02F 1/1339; G02F 1/1334; G02F 1/137; B32B 17/10; C03C 17/42; E06B 9/24; E06B 3/66; B60J 3/04

(52) U.S. Cl. CPC E06B 3/6722; E06B 2009/2464; G02F 1/1334; G02F 1/137; B32B 17/10036; B32B 17/10504; B32B 17/10761; B32B 17/10174; C03C 17/42; E06B 9/24; E06B 3/6608; B60J 3/04; G02F 2201/50; B32B 2605/006; C03C 2217/21; C03C 2217/78; C03C 2218/153; G02F 1/1339

(57) ABSTRACT

A composite pane having a functional element having electrically controllable optical properties, includes a stack sequence of an outer pane, a first intermediate layer, a second intermediate layer, and an inner pane, the intermediate layers containing a thermoplastic polymer film having a plasticizer, a functional element having electrically controllable optical properties is arranged, at least in sections, between the first and second intermediate layers, and the functional element is a polymer dispersed liquid crystal functional element and includes a second stack sequence of a first carrier film, an active layer, and a second carrier film. An exit surface of the active layer is sealed, at least in sections, on a lateral surface of the functional element by a barrier layer. The barrier layer substantially prevents the diffusion of plasticizer through the barrier layer, and is produced by a vacuum-based thin-film deposition method.

The invention relates to a functional element having electrically controllable optical properties, a composite pane having a functional element, and in particular a windshield or a roof panel of a vehicle having an electrically controllable sun visor, and a method for production thereof.

In the vehicle sector and in the construction sector, composite panes with electrically controllable functional elements are often used as sun screens or as privacy screens. Thus, for example, windshields are known in which a sun visor is integrated in the form of a functional element having electrically controllable optical properties. In particular, the transmittance or scattering behavior of electromagnetic radiation in the visible range is electrically controllable. The functional elements are usually film-like and are laminated into or glued onto a composite pane. In the case of windshields, the driver can, for example, control the transmittance behavior of the pane itself relative to sunlight. Thus, a conventional mechanical sun visor can be dispensed with. As a result, the weight of the vehicle can be reduced and space gained in the roof region. In addition, the electrical control of the sun visor is more convenient than the manual folding down of the mechanical sun visor.

Windshields with such electrically controllable sun visors are, for example, known from DE 102013001334 A1, DE 102005049081 B3, DE 102005007427 A1, and DE 102007027296 A1.

Typical electrically controllable functional elements contain electrochromic layer structures or single particle device (SPD) films. Further possible functional elements for realizing an electrically controllable sun screen are so-called PDLC functional elements (polymer dispersed liquid crystal). Their active layer contains liquid crystals that are embedded in a polymer matrix. When no voltage is applied, the liquid crystals are randomly oriented, resulting in strong scattering of the light passing through the active layer. When a voltage is applied on the surface electrodes, the liquid crystals align themselves in a common direction and the transmittance of light through the active layer is increased. The PDLC functional element acts less by reducing total transmittance, but, instead, by increasing scattering to ensure glare protection. PDLC functional elements are known, for example, from US 20150301367 A1.

Prior art, laminated functional elements and, in particular, PDLC functional elements often present, in the edge region, undesirable aging phenomena, such as brightening and changes in shading.

JP 2008225399 discloses a liquid crystal display element on a flexible substrate, such as a plastic film, wherein the lateral surfaces have a gas barrier layer that prevents the penetration of gas via a lateral surface of the substrate.

The object of the present invention is to provide an improved functional element having electrically controllable optical properties that is improved in particular in terms of its resistance to aging.

The object of the present invention is accomplished by a functional element in accordance with the independent claim 1. Preferred embodiments are apparent from the dependent claims.

A functional element according to the invention having electrically controllable optical properties includes at least one (second) stack sequence of at least a first carrier film, an active layer, and a second carrier film, wherein at least one exit surface of the active layer on at least one lateral surface of the functional element is sealed, at least in sections, by at least one barrier layer.

The stack sequence according to the invention preferably includes at least: a first carrier film, a first surface electrode, an active layer, a second surface electrode, and a second carrier film, which are arranged one above another in this order. The stack sequence is, for example, a prefabricated film that has a suitable size and shape.

Stack sequences of films according to the invention typically have a large surface area but only a low total thickness. In the following, the large surfaces of the stack sequence are referred to as the “surface of the upper side” and the “surface of the lower side”, and the surfaces orthogonal thereto, which have only a low width (corresponding to the direction of the low total thickness), are referred to as “lateral surfaces”.

The active layer is bounded on both its large surfaces, in each case, by a carrier film and, optionally, in each case, by a surface electrode. Arranged on the lateral surfaces of the stack sequence of a first carrier film, a first surface electrode, an active layer, a second surface electrode, and a second carrier film are in each case the lateral surfaces of the carrier films, of the surface electrodes, and of the active layer. Since the active layer is covered on its large surfaces by surface electrodes and carrier films, it is only accessible to an external environment on the lateral surfaces of the stack sequence. The respective sections of the active layer on the lateral surfaces of the stack sequence are referred to in the context of the invention as “exit surfaces” of the active layer.

The invention is based on the finding of the inventors that aging of an electrically controllable optical functional element occurs substantially through penetration of harmful substances via the exit surface of the active layer or the exit surfaces of the surface electrodes into the interior of the functional element and changes the optical properties of the functional element undesirably, for example, by brightening or by changing the transmittance of the functional element, starting at its side edges. By sealing the functional element with a suitable barrier layer, the diffusion of harmful substances into the functional element via its lateral surface is inhibited or prevented. The above-mentioned aging phenomena are thus significantly reduced or completely prevented.

In an advantageous embodiment of a functional element according to the invention, the exit surfaces of the active layer are sealed completely with the barrier layer on all lateral surfaces. Thus, particularly reliable sealing of the active layer of the functional element and particularly good aging resistance of the functional element are achieved.

In another advantageous embodiment of a functional element according to the invention, at least one of the lateral surfaces is completely sealed and preferably all lateral surfaces are completely sealed with the barrier layer. Thus, even better sealing of the active layer of the functional element and even better aging resistance of the functional element are achieved.

In the context of this invention, “sealed” means that the corresponding section of a surface is completely covered with the barrier layer as a protective layer and is thus made more resistant and more durable, in particular against the diffusion of harmful substances such as moisture, but also, in particular, of plasticizers from the surroundings that penetrate into the interior of the functional element and in particular into the active layer.

In another advantageous embodiment of a functional element according to the invention, all outer surfaces, i.e., in particular, all lateral surfaces, the upper side, and the lower side are completely sealed with the barrier layer. Thus, even better sealing of the active layer of the functional element and even better aging resistance of the functional element are achieved. Furthermore, an even more homogeneous visual impression of the functional element is achieved.

The barrier layer according to the invention is preferably in direct and immediate contact with the functional element. For example, no separate adhesive or other intermediate layer is situated between the barrier layer and the stack sequence of the functional element.

The barrier layer according to the invention is preferably implemented such that it prevents the diffusion of plasticizer through the barrier layer to the same extent or to a greater extent as the diffusion of plasticizer through the carrier films.

The barrier layer according to the invention is preferably single ply or multi-ply, for example, two-ply, three-ply, four-ply, or five-ply. The individual plies of the barrier layer are also referred to in the following as “individual layers” and can be made of the same material or of different materials.

The individual layer or the individual layers of a multi-ply barrier layer according to the invention preferably contain a transparent material. In the context of the invention, “transparent” means a barrier layer that has transmittance in the visible spectral range greater than 50%, preferably greater than 70%, and in particular greater than 90%. For panes or for pane sections that are not in the traffic-relevant field of vision of the driver, for example, for roof panels or in the upper region of the windshield, or when a special darkening is desired, the transmittance can, however, even be much lower, for example, greater than 5%. In particular, the barrier layer can be tinted or colored.

In an advantageous embodiment of the invention, the individual layer or the individual layers are metal-oxide based, metal nitride-based, or metal oxynitride-based, wherein the metal is preferably silicon (Si), aluminum (Al), tantalum (Ta), or vanadium (V) or a mixture thereof.

In the context of the present invention, the term “based” means that the material consists substantially of the metal oxide, metal nitride, or metal oxynitride, preferably up to at least 80 wt.-%, particularly preferably up to at least 90 wt.-%, and in particular up to at least 95 wt.-%. In the case of metal oxides, metal nitrides, or metal oxynitrides, that are, in particular, produced by chemical vapor deposition such as plasma enhanced vapor deposition, the term “based” includes the fact that in addition to the metal oxides, metal nitrides, or metal oxynitrides, small quantities of residues of the process gases, such as carbon and hydrogen, can also be included as organic residues of organometallic compounds.

Particularly preferred individual layers are silicon oxide-based, silicon nitride-based, or silicon oxynitride-based. In the case of silicon oxide-based individual layers, the silicon oxide SiOₓ is preferably substoichiometric, particularly preferably with 1≤x<2 or stoichiometric (x=2). It can, however, also be hyperstoichiometric.

In a particularly preferred embodiment, the barrier layer according to the invention contains or consists of at least one silicon oxide-based individual layer. The silicon-based individual layer can preferably contain small production-related amounts of carbon and hydrogen. Such an individual layer is preferably made of SiOₓC_{y}:H with very low carbon and hydrogen content, where x is preferably from 0.1 to 3 and particularly preferably from 0.2 to 2, and y is preferably less than 0.2 and particularly preferably less than 0.1 and in particular less than 0.03.

Other preferred individual layers contain or consist of organometallic layers, preferably of organosilicon of the type SiOₓC_{y}:H, also referred to in the literature as an SiOₓC_{y}H_{z} layer. Such layers are preferably created by deposition from HMDSO and are then referred to as plasma-polymerized HMDSO layers. Their stoichiometric composition depends on the deposition conditions, i.e., on the process parameters during layer deposition. The organosilicon coating is preferably highly cross-linked. Without intending to be bound to any theory, such coatings can consist of a network of —Si—O—Si, —Si—(CH₂)₂—Si—, and —Si—O—CH₂—Si— units terminated by Si—CHs, Si—CH₂—CH₃, and Si—H— groups.

In an advantageous embodiment of a barrier layer according to the invention, the barrier layer contains or consists of at least one individual layer of organosilicon of the type SiOₓC_{y}:H, where x is preferably from 0.1 to 3 and particularly preferably from 0.2 to 2, and y is preferably greater than 0.3, particularly preferably from 0.3 to 3, and in particular from 0.9 to 2.

The hydrogen content of the organosilicon compound depends on the degree of polymerization and the chemistry of the deposition processes. The ratio of carbon to hydrogen (CᵤHᵥ) can be arbitrary and is preferably from 1:1000 to 1000:1, particularly preferably from 1:10 to 10:1.

In an alternative barrier layer according to the invention, at least one individual layer contains or consists of an organosilicon, wherein the C_{y}H_{z} content of the organosilicon coating is from 20 wt.-% to 80 wt.-%, preferably from 30 wt.-% to 70 wt.-%. Such organosilicon coatings are preferably highly cross-linked and have a polymeric character.

Other preferred individual layers contain or consist of amorphous hydrogenated carbon (a-C:H), preferably amorphous hydrogenated nitrogen-doped carbon (a-C:N:H) or amorphous hydrogenated nitrogen- and silicon-doped carbon (a-C:N:Si:H). These are preferably produced by CVD methods with acetylene (C₂H₂) or acetylene-containing process gases.

Other preferred individual layers contain other transparent ceramic layers and/or polymer layers which can be produced by vapor deposition methods and which reduce or substantially prevent plasticizer diffusion, for example, Parylene, polyvinylidene chloride (PVDC), ethylene vinyl alcohol copolymers (EVOP), or polyacrylates.

A particularly advantageous barrier layer according to the invention contains at least one individual layer, with a material of a ceramic character. The individual layer is preferably silicon oxide-based, silicon nitride-based, silicon oxynitride-based, aluminum oxide-based, tin oxide-based, zinc oxide-based, tin-zinc oxide-based, or contains other mixed oxides. Preferably, individual layers are made of silicon oxide, silicon nitride, silicon oxynitride, aluminum oxide, tin oxide, zinc oxide, tin-zinc oxide, or other transparent mixed oxides or mixed nitrides.

The layers containing metal oxide, metal nitride, or metal oxynitride can, additionally, be doped, for example, with antimony, fluorine, silver, ruthenium, palladium, aluminum, and tantalum.

In a particularly advantageous embodiment, the barrier layer contains at least two, preferably exactly two, exactly three, exactly four, or exactly five, individual layers made of the same material arranged atop one another. This is particularly advantageous with the thin individual layers used here since defects in one of the individual layers can be compensated for by the other individual layer(s).

In a particularly advantageous embodiment, the barrier layer contains exactly one or at least one two-ply layer, also called a double layer or dyad. The double layer preferably consists of a first individual layer with a polymeric character and a second individual layer with a ceramic or inorganic character. The first individual layer is preferably arranged on the side of the double layer facing the functional element. The first individual layer of a double layer is, particularly preferably, arranged directly on the functional element.

The first individual layer preferably contains a polymer or polymerized material. The above-mentioned organosilicon layers of the type SiOₓC_{y}:H with high hydrocarbon content are particularly preferred.

The second individual layer is preferably metal oxide-based, metal nitride-based, or metal oxynitride-based, wherein the metal is particularly preferably silicon. It preferably has only a low hydrocarbon content and has, in particular, a ceramic character.

The invention is based, in particular, on the finding of the inventors that a combination of a first and a second individual layer of the above-mentioned materials is particularly advantageous in terms of preventing the diffusion of plasticizers from the intermediate layers into the active layer of the functional element.

Without intending to be bound to any theory, the advantage of the double layers combined according to the invention with regard to plasticizer-diffusion-inhibiting properties of the individual layers with ceramic or inorganic character is brought into combination with adhesion-improving and defect-masking properties of the polymeric or polymer-like individual layers.

A double layer or a sequence of multiple double layers that consist of a first individual layer made of organosilicon (preferably with high hydrocarbon content) is particularly advantageous. The first individual layer is preferably arranged on the side of the double layer or the double layers facing the functional element. Here, the adhesion-improving and defect-masking properties of the first individual layer and the plasticizer-diffusion-inhibiting of the second individual layer are particularly good.

In the case of the sequence of multiple double layers, it is particularly advantageous for the respective first individual layer (K for ceramic) and the second individual layer (P for polymerized) to be arranged alternatingly one above another in each case; for two double layers, for example, in the sequence (P-K)-(P-K) or in the sequence (K-P)-(K-P) or in the sequence (P-K)-(K-P) or in the sequence (K-P)-(P-K).

For three double layers, for example, in the sequence (P-K)-(P-K)-(P-K) or in the sequence (K-P)-(K-P)-(K-P) or in the sequence (P-K)-(K-P)-(P-K) or in any other permutation of (K-P) and (P-K).

In an advantageous exemplary embodiment, the barrier layer contains a first individual layer of organosilicon with a high hydrocarbon content and a second individual layer, which is silicon oxide-based and, consequently, has only a low hydrocarbon content.

In an advantageous embodiment, one or a plurality of adhesion-improving layers can be arranged between the functional element and the barrier layer. In particular, the surface of the stack sequence of the functional element can be subjected to an adhesion-improving surface treatment. Thus, the stack sequence can be exposed to an argon (Ar) plasma, a nitrogen (N₂) plasma, or an oxygen (O₂) plasma for surface treatment.

In an advantageous embodiment of a functional element according to the invention, the entire barrier layer of one or a plurality of individual layers has, over the exit surface of the active layer, a thickness d (also referred to as material thickness) from 10 nm to 5000 nm (nanometers), preferably from 15 nm to 1000 nm, and particularly preferably from 15 nm to 500 nm. The thickness d is determined orthogonally to the lateral surface over the exit surface of the active layer.

The thickness d_{1,2} of the individual layers over the exit surface of the active layer is preferably from 5 nm to 5000 nm (nanometers), preferably from 10 nm to 1000 nm, and particularly preferably from 10 nm to 200 nm.

In an advantageous embodiment of a functional element according to the invention, the entire barrier layer consisting of one or a plurality of individual layers has, over the lateral surface of the stack sequence of the functional element, a thickness d (also referred to as material thickness) from 10 nm to 5000 nm (nanometers), preferably from 15 nm to 1000 nm and particularly preferably from 15 nm to 500 nm. The thickness d is determined orthogonally to the lateral surface over the exit surface of the active layer.

Barrier layers according to the invention can be produced by all suitable deposition methods. Particularly suitable are vapor deposition methods, which enable controlled production of particularly thin barrier layer thicknesses d.

The following deposition methods are particularly suitable for producing barrier layers according to the invention:
physical vapor deposition (PVD), particularly preferably
   evaporation, such as
      thermal evaporation,
      electron beam evaporation
      laser beam evaporation
      ion-assisted depoisiton (IAD), or
      arc evaporation
   or
   cathodic sputtering (sputtering), such as
      magnetron sputtering
atomic layer deposition, such as
   plasma-enhanced atomic layer deposition (PEALD) and/or
   chemical vapor deposition (CVD), particularly preferably
      plasma-enhanced chemical vapor deposition (PECVD)
      low pressure chemical vapor deposition (LPCVD)
      low temperature-low pressure PECVD.

For functional elements with polymer carrier films and temperature-sensitive active layers, the above-mentioned plasma-enhanced methods such as PECVD and PEALD are particularly suitable since they allow deposition at only low substrate temperatures.

A composite pane according to the invention comprises at least one (first) stack sequence of an outer pane, a first intermediate layer, a second intermediate layer, and an inner pane, wherein the intermediate layers contain at least one thermoplastic polymer film with at least one plasticizer and wherein a functional element having electrically controllable optical properties is arranged at least in sections between the first intermediate layer and the second intermediate layer.

When the functional element is laminated into a composite pane, the diffusion of plasticizers out of the intermediate layers into the interior of the functional element results, with aging, in brightening or a change in transmittance that negatively affects the through-vision, functionality, and aesthetics of the entire composite pane. By sealing the functional element with a suitable barrier layer that inhibits or prevents the diffusion of plasticizers out of the intermediate layer into the functional element and, in particular, into the lateral surface of the functional element, such aging phenomena are significantly reduced or completely prevented.

The composite pane can, for example, be the windshield or the roof panel of a vehicle or another vehicle glazing, for example, a glass partition in a vehicle, preferably in a rail vehicle or a bus. Alternatively, the composite pane can be an architectural glazing, for example, in an outer façade of a building or a glass partition in the interior of a building.

The terms “outer pane” and “inner pane” arbitrarily describe two different panes. In particular, the outer pane can be referred to as a first pane; and the inner pane, as a second pane.

In the context of the invention, when the composite pane is intended, in a window opening of a vehicle or of a building, to separate an interior space from the external environment, the pane (second pane) facing the interior (vehicle interior) is referred to as the “inner pane”. The pane (first pane) facing the external environment is referred to as the “outer pane”. However, the invention is not limited to this.

The composite pane according to the invention contains a functional element according to the invention having electrically controllable optical properties, which is arranged, at least in sections, between a first intermediate layer and a second intermediate layer. The first and second intermediate layer usually have the same dimensions as the outer pane and the inner pane. The functional element is preferably film-like.

In an advantageous embodiment of a composite pane according to the invention, the intermediate layer contains a polymer, preferably a thermoplastic polymer.

In a particularly advantageous embodiment of a composite pane according to the invention, the intermediate layer contains at least 3 wt.-%, preferably at least 5 wt.-%, particularly preferably at least 20 wt.-%, even more preferably at least 30 wt.-%, and in particular at least 40 wt.-% of a plasticizer. The plasticizer preferably contains or consists of triethylene glycol-bis-(2-ethylhexanoate).

Plasticizers are chemicals that make plastics softer, more flexible, smoother, and/or more elastic. They shift the thermoelastic range of plastics to lower temperatures such that the plastics have the desired more elastic properties in the range of the temperature of use. Other preferred plasticizers are carboxylic acid esters, in particular low-volatility carboxylic acid esters, fats, oils, soft resins, and camphor. Other plasticizers are preferably aliphatic diesters of tri- or tetraethylene glycol. Particularly preferably used as plasticizers are 3G7, 3G8, or 4G7, where the first digit indicates the number of ethylene glycol units and the last digit indicates the number of carbon atoms in the carboxylic acid portion of the compound. Thus, 3G8 represents triethylene glycol-bis-(2-ethylhexanoate), in other words, a compound of the formula C₄H₉CH(CH₂CH₃)CO(OCH₂CH₂)₃O₂CCH(CH₂CH₃)C₄H₉.

In another particularly advantageous embodiment of a composite pane according to the invention, the intermediate layer contains at least 60 wt.-%, preferably at least 70 wt.-%, particularly preferably at least 90 wt.-%, and in particular at least 97 wt.-% polyvinyl butyral.

The thickness of each intermediate layer is preferably from 0.2 mm to 2 mm, particularly preferably from 0.3 mm to 1 mm, in particular from 0.3 mm to 0.8 mm, for example, 0.76 mm.

In an advantageous embodiment of a functional element according to the invention, the barrier layer is implemented such that it prevents the diffusion of plasticizers out of the intermediate layer through the barrier layer.

In a particularly advantageous embodiment of a functional element according to the invention, the barrier layer is plasticizer-free, i.e., without specific addition of a plasticizer.

The controllable functional element typically comprises a thin, active layer between two surface electrodes. The active layer has the controllable optical properties that can be controlled via the voltage applied to the surface electrodes.

In a composite pane according to the invention, the surface electrodes and the active layer are typically arranged substantially parallel to the surfaces of the outer pane and the inner pane.

The surface electrodes are electrically connected to an external voltage source in a manner known per se. The electrical contacting is realized by suitable connecting cables, for example, foil conductors, which are optionally connected to the surface electrodes via so-called “bus bars”, for example, strips of an electrically conductive material or electrically conductive imprints.

The surface electrodes are preferably designed as transparent, electrically conductive layers. The surface electrodes preferably contain at least a metal, a metal alloy, or a transparent conducting oxide (TCO). The surface electrodes can contain, for example, silver, gold, copper, nickel, chromium, tungsten, indium tin oxide (ITO), gallium-doped or aluminum-doped zinc oxide, and/or fluorine-doped or antimony-doped tin oxide. The surface electrodes preferably have a thickness from 10 nm to 2 μm, particularly preferably from 20 nm to 1 μm, most particularly preferably from 30 nm to 500 nm.

In addition to the active layer and the surface electrodes, the functional element can have other layers known per se, for example, barrier layers, blocking layers, antireflective layers, protective layers, and/or smoothing layers.

The functional element is preferably present as a multilayer film with two outer carrier films. In such a multilayer film, the surface electrodes and the active layer are arranged between the two carrier films. Here, the term “outer carrier film” means that the carrier films form the two surfaces of the multilayer film. The functional element can thus be provided as a laminated film that can be processed advantageously. The carrier films advantageously protect the functional element against damage, in particular corrosion. The multilayer film includes, in the order indicated, at least a carrier film, a surface electrode, an active layer, another surface electrode, and another carrier film. The carrier film carries, in particular, the surface electrodes and gives a liquid or soft active layer the necessary mechanical stability.

The carrier films preferably contain at least one thermoplastic polymer, particularly preferably plasticizer-poor or plasticizer-free polyethylene terephthalate (PET). This is particularly advantageous with regard to the stability of the multilayer film. The carrier films can, however, also contain or consist of other plasticizer-poor or plasticizer-free polymers, for example, ethylene vinyl acetate (EVA), polypropylene, polycarbonate, polymethyl methacrylate, polyacrylate, polyvinyl chloride, polyacetate resin, casting resins, acrylates, fluorinated ethylene propylenes, polyvinyl fluoride, and/or ethylene-tetrafluoroethylene. The thickness of each carrier film is preferably from 0.02 mm to 1 mm, particularly preferably from 0.04 mm to 0.2 mm.

Typically, the carrier films have in each case an electrically conductive coating that faces the active layer and functions as a surface electrode.

The functional element according to the invention is preferably a PDLC (polymer dispersed liquid crystal) functional element. The active layer of a PDLC functional element contains liquid crystals that are embedded in a polymer matrix. When no voltage is applied on the surface electrodes, the liquid crystals are oriented in a disorderly manner, resulting in strong scattering of the light passing through the active layer. When a voltage is applied on the surface electrodes, the liquid crystals align themselves in a common direction and the transmittance of light through the active layer is increased. Alternatively, functional elements and, in particular, PDLC functional elements can be used that are transparent when no voltage is applied (0 V) and scatter strongly when a voltage is applied.

In principle, however, it is also possible to use other types of controllable functional elements, for example, electrochromic functional elements or SPD (suspended particle device) functional elements. The controllable functional elements mentioned and their functionality are known per se to the person skilled in the art such that a detailed description can be dispensed with here.

Functional elements are commercially available as multilayer films. The functional element is typically cut in the desired shape and size from a multilayer film with relatively large dimensions. This can be done mechanically, for example, using a knife. In an advantageous embodiment, the cutting is done by laser. It has been shown that, in this case, the lateral surface is more stable than with mechanical cutting. With mechanically cut lateral surfaces, there can be the risk that the material retracts, so to speak, which is noticeable visually and adversely affects the aesthetics of the pane.

In a composite pane according to the invention, the functional element is joined to the outer pane via a region of the first intermediate layer and to the inner pane via a region of the second intermediate layer. The intermediate layers are preferably arranged sheet-wise one over another and laminated together with the functional element inserted between the two layers.

The regions of the intermediate layers overlapping the functional element then form the regions that connect the functional element to the panes. In other regions of the pane where the intermediate layers make direct contact with one another, they can fuse during lamination such that the two original layers are possibly no longer recognizable and, instead, there is a homogeneous intermediate layer.

An intermediate layer can, for example, be formed by a single thermoplastic film. An intermediate layer can also be implemented as a two-ply, three-ply, or multi-ply film stack, wherein the individual films have the same or different properties. An intermediate layer can also be formed from sections of different thermoplastic films whose lateral surfaces are adjacent one another.

In an advantageous further development of a composite pane according to the invention, the region of the first or the second intermediate layer via which the functional element is joined to the outer pane or the inner pane is tinted or colored. The transmittance of this region in the visible spectral range is thus reduced compared to a non-tinted or non-colored layer. The tinted/colored region of the intermediate layer thus reduces the transmittance of the windshield in the region of the sun visor. In particular, the aesthetic impression of the functional element is improved because the tinting results in a neutral appearance that affects the observer more pleasantly.

In the context of the invention, “electrically controllable optical properties” means those properties that are infinitely controllable but also those that can be switched between two or more discrete states.

The electrical control of the sun visor is done, for example, by means of switches, rotary or slide controls that are integrated into the dashboard of the vehicle. However, a switch area for controlling the sun visor can also be integrated into the windshield, for example, a capacitive switch area. Alternatively, or additionally, the sun visor can be controlled by contactless methods, for example, by gesture recognition, or as a function of the state of the pupil or eyelid determined by a camera and suitable evaluation electronics. Alternatively, or additionally, the sun visor can be controlled by sensors that detect incidence of light on the pane.

The tinted or colored region of the intermediate layer preferably has transmittance in the visible spectral range of 10% to 50%, particularly preferably of 20% to 40%. Particularly good results in terms of glare protection and optical appearance are thus obtained.

The intermediate layer can be implemented by a single thermoplastic film, in which the tinted or colored region is produced by local tinting or coloring. Such films can be obtained, for example, by coextrusion. Alternatively, an untinted film section and a tinted or colored film section can be combined to form the thermoplastic layer.

The tinted or colored region can be colored or tinted homogeneously, in other words, can have location-independent transmittance. The tinting or coloring can, however, also be inhomogeneous, in particular, a transmittance progression can be realized. In one embodiment, the transmittance level in the tinted or colored region decreases, at least in sections, with increasing distance from the upper edge. Thus, sharp edges of the tinted or colored area can be avoided such that the transition from the sun visor into the transparent region of the windshield is gradual, which appears more attractive aesthetically.

In an advantageous embodiment, the region of the first intermediate layer, i.e., the region between the functional element and the outer pane is tinted. This creates a particularly aesthetic impression when viewing the outer pane from above. The region of the second intermediate layer between the functional element and the inner pane can optionally also be colored or tinted.

The composite pane having an electrically controllable functional element can advantageously be implemented as a windshield with an electrically controllable sun visor. Such a windshield has an upper edge and a lower edge as well as two side edges extending between the upper edge and the lower edge. “Upper edge” refers to that edge that is intended to point upward in the installation position. “Lower edge” refers to that edge that is intended to point downward in the installation position. The upper edge is often referred to as the roof edge; the lower edge, as the engine edge.

Windshields have a central field of vision, for which high optical quality requirements are established. The central field of vision has to have high light transmittance (typically greater than 70%). Said central field of vision is, in particular, that field of vision that is referred to by the person skilled in the art as field of vision B, vision area B, or zone B. The field of vision B and its technical requirements are specified in Regulation No. 43 of the United Nations Economic Commission for Europe (UN/ECE) (ECE-R43, “Uniform Provisions concerning the Approval of Safety Glazing Materials and Their Installation on Vehicles”). The field of vision B is defined there in Appendix 18.

The functional element is then advantageously arranged above the central field of vision (field of vision B). This means that the functional element is arranged in the region between the central field of vision and the upper edge of the windshield. The functional element does not have to cover the entire region, but is positioned completely within this region and does not protrude into the central field of vision. In other words, the functional element has a shorter distance from the upper edge of the windshield than the central field of vision. Thus, the transmittance of the central field of vision is not adversely affected by the functional element, which is positioned at a location similar to that of a conventional mechanical sun visor when folded down.

The windshield is preferably intended for a motor vehicle, particularly preferably for a passenger car.

In a preferred embodiment, the functional element, more precisely the lateral surfaces of the functional element with the barrier layer, is circumferentially surrounded by a third intermediate layer. The third intermediate layer is implemented frame-like with a recess into which the functional element is inserted. The third intermediate layer can also be formed by a thermoplastic film, in which the recess was made by cutting. Alternatively, the third intermediate layer can also be composed of a plurality of film sections around the functional element. The intermediate layer is preferably formed from a total of at least three thermoplastic layers arranged sheet-wise one over another, wherein the middle layer has a recess in which the functional element is arranged. During production, the third intermediate layer is arranged between the first and the second intermediate layer, with the lateral surfaces of all intermediate layers preferably arranged congruently. The third intermediate layer preferably has approx. the same thickness as the functional element. This compensates for the local difference in thickness of the windshield introduced by the locally limited functional element such that glass breakage during lamination can be avoided.

The lateral surfaces of the functional element visible when looking through the windshield are preferably arranged flush with the third intermediate layer such that no gap exists between the lateral surface of the functional element and the associated lateral surface of the intermediate layer. This applies in particular to the bottom surface of the functional element, which is typically visible. Thus, the boundary between the third intermediate layer and the functional element is visually less conspicuous.

In a preferred embodiment, the lower edges of the functional element and of the tinted region of the intermediate layer(s) are adapted to the shape of the upper edge of the windshield, creating a visually more appealing appearance. Since the upper edge of a windshield is typically curved, in particular concavely curved, the lower edge of the functional element and of the tinted region are also preferably curved. Particularly preferably, the lower edges of the functional element are substantially parallel to the upper edge of the windshield. It is, however, also possible to construct the sun visor from two straight halves arranged at an angle relative to each other and approximating the shape of the upper edge in a V shape.

In an embodiment of the invention, the functional element is divided into segments by isolation lines. The isolation lines are in particular introduced into the surface electrodes such that the segments of the surface electrode are electrically isolated from one another. The individual segments are connected to the voltage source independently of one another such that they can be actuated separately. Thus, different regions of the sun visor can be switched independently. Particularly preferably, the isolation lines and the segments are arranged horizontally in the installation position. Thus, the height of the sun visor can be controlled by the user. The term “horizontal” is to be interpreted broadly here and refers to a direction of extension that, in a windshield, runs between the side edges of the windshield. The isolation lines do not necessarily have to be straight, but can also be slightly curved, preferably adapted to any curvature of the upper edge of the windshield, in particular substantially parallel to the upper edge of the windshield. Vertical isolation lines are, of course, also conceivable.

The isolation lines have, for example, a width of 5 μm to 500 μm, in particular 20 μm to 200 μm. The width of the segments, i.e., the distance between adjacent isolation lines can be suitably selected by the person skilled in the art according to the requirements of the individual case.

The isolation lines can be introduced by laser ablation, mechanical cutting, or etching during production of the functional element. Already laminated multilayer films can also be subsequently segmented by laser ablation.

The upper edge and the adjacent lateral surface or all lateral surfaces of the functional element are concealed in vision through the composite pane preferably by an opaque masking print or by an outer frame. Windshields typically have a surrounding peripheral masking print made of an opaque enamel, which serves in particular to protect the adhesive used for installation of the window against UV radiation and to visually conceal it. This peripheral masking print is preferably used to also conceal the upper edge and the lateral surface of the functional element as well as the necessary electrical connections. The sun visor is then advantageously integrated into the appearance of the windshield and only its lower edge is potentially discernible to the observer. Preferably, both the outer pane and the inner pane have a masking print such that through-vision is prevented from both sides.

The functional element can also have recesses or holes, for instance, in the region of so-called sensor windows or camera windows. These regions are provided to be equipped with sensors or cameras whose function would be impaired by a controllable functional element in the beam path, for example, rain sensors. It is also possible to realize the sun visor with at least two functional elements separated from one another, with a distance between the functional elements providing space for a sensor window or a camera window.

The functional element (or the totality of the functional elements in the above-described case of a plurality of functional elements) is preferably arranged over the entire width of the composite pane or of the windshield, minus an edge region on both sides having a width of, for example, 2 mm to 20 mm. The functional element also preferably has a distance of, for example, 2 mm to 20 mm from the upper edge. The functional element is thus encapsulated within the intermediate layer and protected against contact with the surrounding atmosphere and corrosion.

The outer pane and the inner pane are preferably made of glass, particularly preferably of soda lime glass, as is customary for window panes. The panes can, however, also be made of other types of glass, for example, quartz glass, borosilicate glass, or aluminosilicate glass, or rigid clear plastics, for example, polycarbonate or polymethyl methacrylate. The panes can be clear, or also tinted or colored. Windshields must have adequate light transmittance in the central field of vision, preferably at least 70% in the primary through-vision zone A per ECE-R43.

The outer pane, the inner pane, and/or the intermediate layer can have further suitable coatings known per se, for example, antireflection coatings, nonstick coatings, anti-scratch coatings, photocatalytic coatings, or solar protection coatings, or low-E coatings.

The thickness of the outer pane and the inner pane can vary widely and thus be adapted to the requirements of the individual case. The outer pane and the inner pane preferably have thicknesses of 0.5 mm to 5 mm, particularly preferably of 1 mm to 3 mm.

The invention further includes a method for producing a functional element according to the invention having electrically controllable optical properties, wherein at least

a) a stack sequence of at least a first carrier film, an active layer, and a second carrier film is provided, and
b) an exit surface of the active layer on at least one lateral surface of the functional element is sealed, at least in sections and preferably completely, with a barrier layer by a vacuum-based thin-film deposition method.

Preferably, a stack sequence of at least a first carrier film, a first surface electrode, an active layer, a second surface electrode, and a second carrier film is provided.

The stack sequence is, for example, a prefabricated film that is brought to a suitable size and shape.

The vacuum-based thin-film deposition method according to the invention is preferably one of the following methods:
physical vapor deposition (PVD), particularly preferably
   evaporation, such as
      thermal evaporation,
      electron beam evaporation
      laser beam evaporation
      ion-assisted deposition (IAD), or
      arc evaporation
or
   cathodic sputtering (sputtering), such as
      magnetron sputtering
atomic layer deposition (ALD), such as
   plasma-enhanced atomic layer deposition, PEALD) or
   chemical vapor deposition (CVD), particularly preferably
      plasma-enhanced chemical vapor deposition, (PECVD)
      low pressure chemical vapor deposition (LPCVD)
      low temperature-low pressure PECVD.

The barrier layers deposited by vacuum-based thin-film deposition methods preferably contain the above-mentioned materials according to the invention and the above-mentioned structure according to the invention.

A further aspect of the invention includes a PDLC functional element (5) having electrically controllable optical properties, comprising
a stack sequence of at least:
   a first carrier film made of PET,
   a PDLC layer as an active layer, and
   a second carrier film made of PET,
wherein at least the lateral surfaces of the functional element are sealed with at least one barrier layer produced by plasma-enhanced chemical vapor deposition (PECVD).

The barrier layer preferably contains at least one silicon oxide-based individual layer, particularly preferably a double layer consisting of an organosilicon-containing individual layer (with high hydrocarbon content) and a silicon oxide-based individual layer (with low hydrocarbon content).

In an advantageous further development of the method according to the invention, an organosilicon compound is used as a process gas in the PECVD process, preferably disiloxane, particularly preferably hexamethyl disiloxane (HMDSO), tetramethyl disiloxane (TMDSO), or tetraethoxysilane (TEOS). Such process gases are particularly well-suited for producing an organosilicon-containing individual layer. Particularly suitable is deposition with HMDSO as process gas, since the deposition can be carried out at low temperatures (usually 50° C. to 100° C.), and the deposition is also possible on temperature-sensitive surfaces such as plastics.

In an advantageous further development of the method according to the invention, an organosilicon-compound is used as a first process gas in the PECVD process, preferably disiloxane, particularly preferably hexamethyl disiloxane (HMDSO), or tetramethyl disiloxane (TMDSO) and oxygen (O₂) is used as a second process gas. Preferably, the oxygen is introduced into the plasma with an excess of oxygen, preferably with a ratio of HMDSO:O₂ of 1:2 to 1:100, preferably 1:5 to 1:15, and particularly preferably of 1:8 to 1:12, and, for example, 1:10. Such process gas mixtures are particularly well-suited for producing silicon oxide-based individual layers with only low hydrocarbon residues.

Alternatively, barrier layers of amorphous hydrogenated carbon (a-C:H) can be produced, alone or in combination with others and in particular with silicon oxide-based individual layers. Here, acetylene is preferably used as process gas.

Alternatively, barrier layers of amorphous hydrogenated nitrogen-doped carbon (a-C:N:H) can be produced, alone or in combination with others and in particular with silicon oxide-based individual layers. Here, preferably, a mixture of acetylene and nitrogen is used as process gas.

Alternatively, barrier layers of amorphous hydrogenated nitrogen- and silicon-doped carbon (a-C:N:Si:H) can be produced, alone or in combination with others and in particular with silicon oxide-based individual layers. Here, a mixture of acetylene, nitrogen, and HMDSO is preferably used as process gas.

In an advantageous further development of the method according to the invention, the surface of the stack sequence can be subjected to an adhesion-improving surface treatment before deposition of the barrier layer or between deposition of the individual layers. Thus, the stack sequence or the individual layer can be exposed to an Ar plasma, a nitrogen (N₂) plasma, or to an oxygen (O₂) plasma for surface treatment.

In an advantageous further development of the method according to the invention, the functional element is completely sealed on all outer surfaces by the barrier layer. For this purpose, for example, the support surface of the functional element on a carrier or the contact surface of a holder can be changed during the coating or between two coating steps or, for example, the functional element can be rotated or turned over.

Another aspect of the invention relates to a method for producing a composite pane according to the invention, wherein in a subsequent step

c) an outer pane, a first intermediate layer, the functional element according to the invention having electrically controllable optical properties, a second intermediate layer, and an inner pane are arranged one above another in this order, and
d) the outer pane and the inner pane are joined by lamination, wherein an intermediate layer with an embedded functional elements is formed from the first intermediate layer and the second intermediate layer.

In an advantageous further development of method according to the invention, in step c), a third intermediate layer that surrounds the functional element is arranged between the first intermediate layer and the second intermediate layer.

The electrical contracting of the surface electrodes of the functional element is preferably done before laminating the composite pane.

Any prints that are present, for example, opaque masking prints or printed busbars for the electrical contacting of the functional element are preferably applied by screen printing.

The lamination is preferably done under the action of heat, vacuum, and/or pressure. Methods known per se can be used for lamination, for example, autoclave methods, vacuum bag methods, vacuum ring methods, calender methods, vacuum laminators, or combinations thereof.

The invention further includes the use of a composite pane according to the invention having an electrically controllable functional element as interior glazing or exterior glazing in a vehicle or a building, wherein the electrically controllable functional element is used as a sun screen or as a privacy screen.

The invention further includes the use of a composite pane according to the invention as a windshield or roof panel of a vehicle, wherein the electrically controllable functional element is used as a sun visor.

The invention further includes the use of a functional element according to the invention in an interior glazing or exterior glazing in a vehicle or a building, wherein the electrically controllable functional element is used as a sun screen or as a privacy screen.

The invention further includes the use of a composite pane according to the invention as a windshield or roof panel of a vehicle, wherein the electrically controllable functional element is used as a sun visor.

A major advantage of the invention consists in that, with composite panes as a windshield, a conventional vehicle-roof-mounted, mechanically foldable sun visor can be dispensed with. Consequently, the invention thus also includes a vehicle, preferably a motor vehicle, in particular a passenger car, that has no such conventional sun visor.

The invention also includes the use of a tinted or colored region of an intermediate layer for joining a functional element having electrically controllable optical properties to an outer pane or an inner pane of a windshield, wherein an electrically controllable sun visor is realized by means of the tinted or colored region of the intermediate layer and the functional element.

The invention is explained in detail with reference to drawings and exemplary embodiments. The drawings are schematic representations and not true to scale. The drawings in no way restrict the invention. They depict:

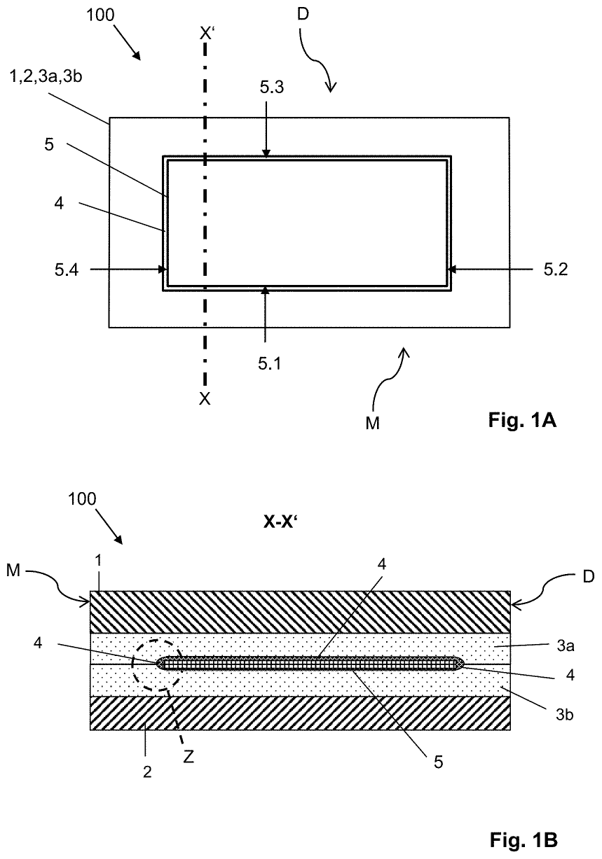

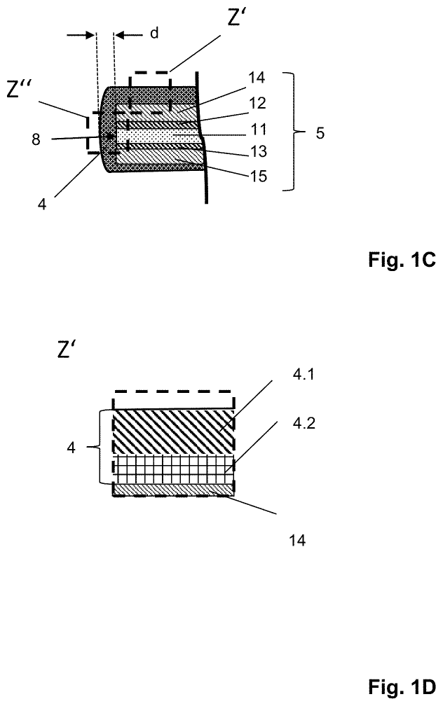

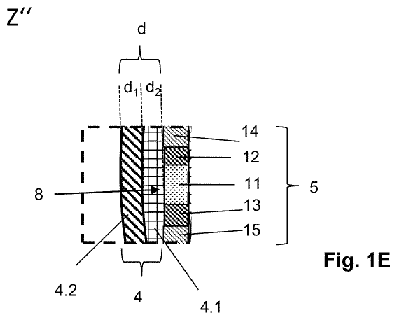

FIG. 1A a plan view of a first embodiment of a composite pane according to the invention with a functional element according to the invention,

FIG. 1B a cross-section through the composite pane of FIG. 1A along the section line X-X′,

FIG. 1C enlarged view of the region Z of FIG. 1B,

FIG. 1D enlarged view of the region Z′ of FIG. 1C,

FIG. 1E enlarged view of the region Z″ of FIG. 1C,

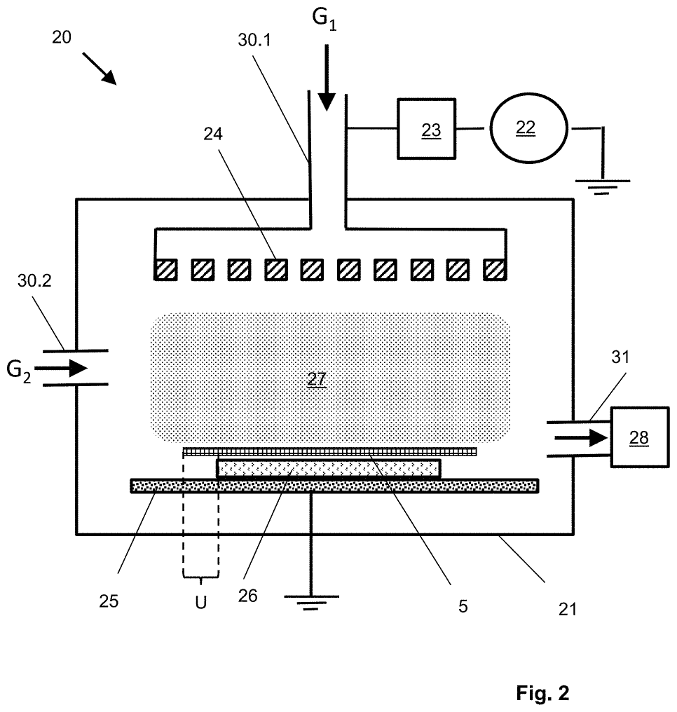

FIG. 2 a schematic representation of an apparatus for depositing a barrier layer according to the invention,

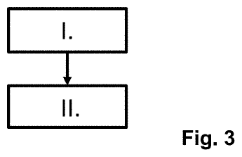

FIG. 3 a flowchart of an exemplary embodiment of the method according to the invention,

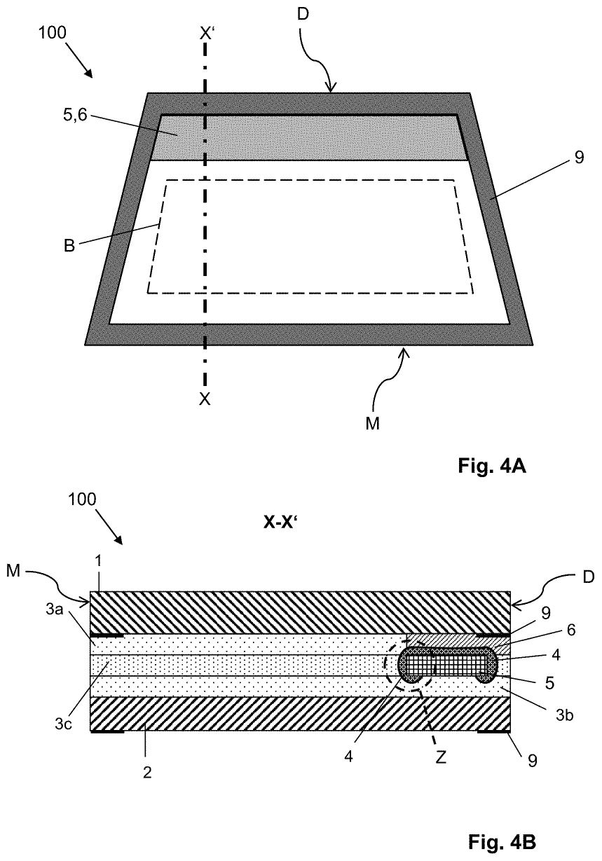

FIG. 4A a plan view of another embodiment of a composite pane according to the invention using the example of a windshield with a sun visor,

FIG. 4B a cross-section through the composite pane of FIG. 4A along the section line X-X′.

FIGS. 1A, 1B, 1C, 1D, and 1E depict in each case a detail of a composite pane according to the invention 100. The composite pane 100 comprises an outer pane 1 and an inner pane 2 joined via a first intermediate layer 3a and a second intermediate layer 3b. The outer pane 1 has a thickness of 2.1 mm and is made, for example, of a clear soda lime glass. The inner pane 2 has a thickness of 1.6 mm and is likewise made, for example, of a clear soda lime glass. The composite pane 100 has a first edge referenced with D that is called the “upper edge” in the following. The composite pane 100 has a second edge referenced with M that is arranged opposite the upper edge D and is called the “lower edge” in the following. The composite pane 100 can be arranged, for example, as architectural glazing in the frame of a window with other panes to form an insulating glazing unit.

A functional element 5 that is controllable in its optical properties via an electrical voltage is arranged between the first intermediate layer 3a and the second intermediate layer 3b. For the sake of simplicity, the electrical leads are not shown.

The controllable functional element 5 is, for example, a PDLC multilayer film consisting of a stack sequence with an active layer 11 between two surface electrodes 12, 13 and two carrier films 14, 15. The active layer 11 contains a polymer matrix with liquid crystals dispersed therein that are oriented as a function of the electrical voltage applied on the surface electrodes, by which means the optical properties can be controlled. The carrier films 14, 15 are made of polyethylene terephthalate (PET) and have a thickness of, for example, 0.125 mm. The carrier films 14, 15 are provided with a coating of ITO facing the active layer 11 and having a thickness of approx. 100 nm which form the surface electrodes 12, 13. The surface electrodes 12, 13 can be connected to the vehicle's electrical system via busbars (not shown) (formed, for example, by a silver-containing screen print) and connection cables (not shown).

The intermediate layers 3a, 3b comprise in each case a thermoplastic film with a thickness of 0.38 mm. The intermediate layers 3a, 3b are made, for example, of 78 wt.-% polyvinyl butyral (PVB) and 20 wt.-% triethylene glycol bis-(2-ethyl hexanoate) as plasticizer.

The functional element 5 has, on all lateral surfaces 5.1, 5.2, 5.3, 5.4, a barrier layer 4, which covers, for example, the entire lateral surfaces 5.1, 5.2, 5.3, 5.4, the entire area of the upper side (i.e., the surface facing the first intermediate layer 3a) of the functional element 5 and, in sections, the area of the lower side (i.e., the surface facing the second intermediate layer 3b) of the functional element 5. Alternatively, the functional element 5 can be completely coated on its outer surfaces, for example, by changing the holders or by turning the functional element during coating or between two coating steps.

The barrier layer 4 reduces or prevents diffusion of plasticizer into the active layer 11, thus increasing the service life of the functional element 5. The thickness (or in other words, the material thickness) d of the barrier material 4 over (i.e., orthogonal to) the exit surface 8 is, for example, at least 50 nm.

FIGS. 1D and 1E depict an exemplary embodiment, in which the barrier layer 4 is implemented in two plies. FIG. 1D depicts an enlarged region Z′ of the upper side of the functional element 5 of FIG. 1C and FIG. 1E the enlarged region of the side edge 5.1 of the functional element 5 with the exit surface 8 of the active layer 11 of FIG. 1C.

The first individual layer 4.1 of the two-ply barrier layer 4 is arranged directly on the stack sequence of the functional element 5. It consists of an organosilicon layer with a layer thickness d₁ of, for example, 50 nm. The first individual layer 4.1 is arranged on all lateral surfaces 5.1-5.4 of the functional element 5, on the surface of the upper side (i.e., the outside of the first carrier film 14) and, in sections, on the surface of the under side (i.e., on the outside of the second carrier film 15).

The second individual layer 4.2 of the two-ply barrier layer 4 is arranged directly on the first individual layer 4.1. It is based on silicon oxide and has a layer thickness d₂ of, for example, 100 nm. Here, the total layer thickness d of the barrier layer 4 is, for example, d=d₁+d₂=150 nm.

The individual layers 4.1,4.2 are deposited on the stack sequence of the functional element 5, for example, with the method described under FIG. 2 and FIG. 3.

Both the first individual layer 4.1 and the second individual layer 4.2 are transparent and colorless such that they do not impair vision through the functional element 5 and are completely invisible to the human eye.

In aging tests, such composite panes 100 with a barrier layer 4 according to the invention show significantly reduced brightening in the edge region of the functional element 5, since diffusion of the plasticizer out of the intermediate layers 3a, 3b into the functional element 5 and resultant degradation of the functional element 5 are avoided.

FIG. 2 depicts an exemplary apparatus for producing a functional element according to the invention 5 and for the exemplary performance of the method according to the invention.

The apparatus comprises a vapor deposition system 20 using the example of a PECVD system. For this, a cathode 24 and anode 25 are arranged in a vacuum chamber 21. A plasma is ignited within a plasma zone 27 between the cathode 24 and the anode 25 by applying a high-frequency alternating field from a high-frequency generator 22 and matching electronics 23 between cathode the 24 and the anode 25. The vacuum is generated by a vacuum pump 28 connected to a gas outlet 31.

At the same time, at least one first process gas G₁ is introduced into the plasma zone 27 through at least one first gas inlet 30.1.

The cathode 24 is, for example, implemented as a spray head cathode. “Spray head cathode” means that the cathode 24 has a large number of holes through which the first process gas G₁ can flow. The cathode 24 is designed such that and connected to the first gas inlet 30.1 such that the first process gas G₁ can flow through the cathode 24 over a wide area into the vacuum chamber 21 and in particular into the plasma zone 27.

A specimen holder 26 is arranged on the anode 25. The specimen holder 26 consists, for example, of a plate, a ring, multiple rings, a grid, or other suitable shapes.

The stack sequence of the functional element 5 to be coated is arranged on the specimen holder 26. The specimen holder 26 can, for example, be implemented in the shape of a frame, as a flat surface, or with multiple support points.

In an advantageous embodiment of a specimen holder 26 according to the invention, the specimen holder is designed such that the functional element 5 protrudes beyond the specimen holder 26 on all sides by an overhang U. This ensures that the entire lateral surfaces 5.1-5.4 are coated on all sides with the barrier material 4. In particular, PECVD methods have particularly good edge covering properties and, consequently, permit particularly good coating of the lateral surfaces 5.1-5.4 that are arranged orthogonally relative to the anode 25.

If vaporous organic precursor compounds (precursor monomers) are introduced into the plasma zone 27 as the first process gas G₁, these precursor compounds are first activated by the plasma. In addition to the radicals thus formed, ions are also generated in a plasma and together with the radicals cause the deposition of layers on the substrate. The gas temperature in the plasma usually increases only slightly; thus, even temperature-sensitive materials can be coated.

Depending on the process gas, ionized molecules can develop as result of the activation which form in the gasphase, for example, molecular fragments as clusters or chains. Then, the molecular fragments condense on the substrate (here, on the functional element 5). When a suitable process gas is selected, the molecular fragments can polymerize on the surface under the influence of substrate temperature, electron and ion bombardment and form a closed layer.

A second process gas G₂ can be introduced into the vacuum chamber 21 via a second gas inlet 30.2. The second gas inlet 30.2 is, for example, implemented as an annular shower. This means that the second gas inlet 30.2 is, for example, routed in a ring shape around the plasma zone 27 such that the second process gas G₂ can flow laterally from all sides into the plasma zone 27 through openings in a ring-shaped tube.

It goes without saying that only the second process gas G₂ can also be introduced into the vacuum chamber 21, i.e., without the simultaneous introduction of the first process gas G₁.

HMDSO or TMDSO, for example, can be used as the first process gas G₁, and, optionally, oxygen (O₂), for example, can be used as the second process gas G₂.

When a process gas G₁ or G₂ that is liquid at room temperature is used, it can be converted into the gas phase using an evaporation unit (not shown).

FIG. 3 depicts a schematic representation for performing the method according to the invention using the example of a PECVD method.

An exemplary embodiment of the method according to the invention for producing a functional element according to the invention (5) having electrically controllable optical properties comprises the following steps:
I.) a stack sequence of at least
   a first carrier film (15),
   an active layer (11), and
   a second carrier film (14)
is provided, and
II.) an exit surface (8) of the active layer (11) is sealed, at least in sections, on at least one lateral surface (5.1, 5.2, 5.3, 5.4) of the functional element (5) by a barrier layer (4), wherein the barrier layer (4) is deposited on the functional element (3) with a PECVD method.

The PECVD method is carried out, for example, in a vacuum chamber 21 of the apparatus depicted in FIG. 2. The energy supply is provided, for example, by multiple magnetrons, operating, for example, at 2.45 GHz, optionally in pulse mode. The standard pressure of the PECVD chamber is, for example, about 5*10⁻⁵ mbar.

PECVD methods have the particular advantage that the substrates to be coated are heated only slightly, which is particularly advantageous for temperature-sensitive PDLC films.

In a preferred exemplary embodiment, an individual layer 4.1 is deposited as the barrier layer 4 on the stack sequence of the functional element 5. For the deposition, vaporized HMDSO is introduced into the plasma zone 27 as the first process gas G₁ via the gas inlet 30.1 and the spray head cathode 21. For example, no second process gas G₂ or only an inert process gas G₂ such as argon is supplied.

The individual layer 4.1 then contains an organosilicon coating of type SiOₓC_{y}:H. Its stoichiometric composition depends on the deposition conditions, i.e., on the process parameters during layer deposition. The organosilicon coating is preferably highly cross-linked. The organosilicon coating consists, for example, of Si₁O_{0.7}C_{1.7}:H.

In another preferred exemplary embodiment, an alternative individual layer 4.1 is deposited as the barrier layer 4 on the stack sequence of the functional element 5. For the deposition, vaporized HMDSO is introduced into the plasma zone 27 as the first process gas G₁ via the gas inlet 30.1 and the spray head cathode 21. At the same time, oxygen (O₂) is introduced as a second process gas G₂ into the plasma zone 27 via the second gas inlet 30.2 and the annular shower.

Advantageously, the first process gas G₁ (HMDSO) is introduced at a ratio to the second process gas G₂ (O₂) of preferably G₁:G₂ of 1:5 to 1:20 and, for example, of 1:10.

As a result of the reaction of the first process gas G₁ of HMDSO with the second process gas G₂ of oxygen, an SiOₓ-based individual layer 4.1 is deposited on the stack sequence. In other words, the individual layer 4.1 consists substantially of SiOₓ, where, for example, x=1.9 and the individual layer 4.1 moreover contains only small amounts of carbon and hydrogen as organic residue of the organosilicon compound of the first process gases G₁. Preferably, the SiOₓ-based individual layer 4.1 contains more than 90 wt.-%.

The respective layer thicknesses d of the barrier layer 4 and the compositions of the barrier layer 4 can be freely selected by a parameter selection familiar to the person skilled in the art, in particular by the deposition time, within the scope of the method according to the invention.

In particular, in addition to individual layers 4.1, multi-ply barrier layers 4 with different compositions can also be deposited.

In another preferred exemplary embodiment, a two-ply barrier layer 4 comprising two individual layers 4.1, 4.2 is deposited, which is depicted by way of example in FIGS. 1C and 1D.

First, a first individual layer 4.1 of, for example, Si₁O_{0.7}C_{1.7}:H is deposited on the stack sequence. For this purpose, as described above, only a first process gas G₁ of HMDSO is introduced into the plasma zone 27.

Then, an SiOₓ-based second individual layer 4.2 is deposited on the first individual layer 4.1. For this purpose, as described above, a first process gas G₁ of HMDSO and a second process gas G₂ of oxygen, for example, at a ratio of 1:10, are introduced into the plasma zone 27.

In another exemplary embodiment, the surface of the stack sequence can be pretreated before deposition of the barrier layer 4, for example, cleaned, etched, or roughened. The stack sequence can, for example, be exposed to the plasma without process gases or only with oxygen as a process gas. It is thus possible to improve the adhesion of the barrier layer 4 deposited thereon.

It goes without saying that, by means of the method according to the invention presented here, other multi-ply barrier layers 4 with different material compositions, material combinations, and material permutations can also be deposited. Thus, in a simple manner, different process gases can be fed into the PECVD system and, as a result, barrier layers with different materials can be deposited.

In particular, by a slow change in the process parameters and, in particular, by a change in the ratio of a first process gas G₁ and a second process gas G₂ during the deposition, gradients in the material composition of the barrier layer 4 can be produced.

The following table shows the results of an aging test for three exemplary functional elements according to the invention Example 1 to 3 with protective layers 4 according to the invention and a prior art Comparative Example without a protective layer according to the invention.

| | Protective layer 4 | | |
|---|---|---|---|
| | | second | Aging |
| | first individual layer 4.1 | individual layer 4.2 | test |
| Example 1 | SiOₓ-based (100 nm) | — | Good |
| Example 2 | SiOₓC_{y}H_{z} (50 nm) | — | Good |
| Example 3 | SiOₓC_{y}H_{z} (50 nm) | SiOₓ-based (100 nm) | Very |
| | | | good |
| Comparative | — | — | Poor |
| Example | | | |

The aging test consists of hot storage of the laminated-in, coated functional element for 4 weeks at 90° C.

Functional elements according to the invention, in which the protective layer 4 consists of a single protective layer 4.1, show, compared to the Comparative Example, significantly improved resistance in the aging test. A two-ply protective layer 4 consisting of a first individual protective layer 4.1 made of organosilicon (SiOₓC_{y}:H) and a silicon oxide-based second individual layer 4.2 show further improved aging resistance.

FIG. 4A and FIG. 4B depict in each case a detail of an exemplary composite pane according to the invention 100 as a windshield having an electrically controllable sun visor. The composite pane 100 of FIGS. 4A and 4B corresponds substantially to the composite pane 100 of FIG. 1A-C such that, in the following, only the differences are discussed.

The windshield comprises a trapezoidal composite pane 100 with an outer pane 1 and an inner pane 2 that are joined to one another via two intermediate layers 3a,3b. The outer pane 1 has a thickness of 2.1 mm and is made of green-colored soda lime glass. The inner pane 2 has a thickness of 1.6 mm and is made of clear soda lime glass. The windshield has an upper edge D facing the roof in the installed position and a lower edge M facing the engine compartment in the installed position.

The windshield is equipped with an electrically controllable functional element 5 according to the invention as a sun visor that is arranged in a region above the central field of vision B (as defined in ECE-R 43). The sun visor is formed by a commercially available PDLC multilayer film as the functional element 5 that is embedded in the intermediate layers 3a,3b. The height of the sun visor is, for example, 21 cm. The first intermediate layer 3a is bonded to the outer pane 1; the second intermediate layer 3b is bonded to the inner pane 2. A third intermediate layer 3c positioned therebetween has a cutout, into which the cut-to-size PDLC multilayer film is inserted precisely, i.e., flush on all sides. The third intermediate layer 3c thus forms, so to speak, a sort of passe-partout for the functional element 5, which is thus encapsulated all around in a thermoplastic material and is protected thereby.

The first intermediate layer 3a has a tinted region 6 that is arranged between the functional element 5 and the outer pane 1. The light transmittance of the windshield is thus additionally reduced in the region of the functional element and the milky appearance of the PDLC functional element 5 in the diffuse state is mitigated. The aesthetics of the windshield are thus significantly more attractive. The first intermediate layer 3a has, in the region 6, for example, average light transmittance of 30%, with which good results are achieved.

The region 6 can be homogeneously tinted. However, it is often visually more appealing if the tinting decreases in the direction of the lower edge of the functional element 5 such that the tinted and the non-tinted regions transition smoothly.

In the case depicted, the lower edges of the tinted region 6 and the lower edge of the PDLC functional element 5 (here, its lateral surface 5.1) are arranged flush with the barrier layer 4. This is, however, not necessarily the case. It is also possible for the tinted region 6 to protrude beyond the functional element 5 or, vice versa, for the functional element 5 to protrude beyond the tinted region 6. In the latter case, it would not be the entire functional element 5 that would be bonded to the outer pane 1 via the tinted region 6.

The windshield has, as is customary, a surrounding peripheral masking print 9 that is formed by an opaque enamel on the interior-side surfaces (facing the interior of the vehicle in the installed position) of the outer pane 1 and of the inner pane 2. The distance of the functional element 5 from the upper edge D and the side edges of the windshield is less than the width of the masking print 9 such that the lateral surfaces of the functional element 5—with the exception of the side edge facing the central field of vision B—are concealed by the masking print 9. The electrical connections (not shown) are also reasonably mounted in the region of the masking print 9 and thus hidden.

The controllable functional element 5 is a multilayer film, consisting of an active layer 11 between two surface electrodes 12, 13 and two carrier films 14, 15. The active layer 11 contains a polymer matrix with liquid crystals dispersed therein, which align themselves as a function of the electrical voltage applied to the surface electrodes, as a result of which the optical properties can be controlled. The carrier films 14, 15 are made of PET and have a thickness of, for example, 0.125 mm. The carrier films 14, 15 are provided with coating of ITO facing the active layer 11 and having a thickness of approx. 100 nm, forming the electrodes 12, 13. The electrodes 12, 13 can be connected to the vehicle's electrical system, via a bus bar (not shown) (formed, for example, by a silver-containing screen print) and via connecting cables (not shown).

A barrier layer 4 is arranged, for example, on the lateral surfaces 5.1, 5.2, 5.3, and 5.4 of the functional element 5, analogously to FIG. 1C. In the example depicted, all lateral surfaces 5.1, 5.2, 5.3, and 5.4 are completely sealed with the barrier layer 4. Thus, the functional element 5 is particularly well protected against aging.

A so-called “high flow PVB”, which has stronger flow behavior compared to standard PVB films, can preferably be used for the intermediate layers 3a, 3b, 3c. The layers thus flow around the barrier film 4 and the functional element 5 more strongly, creating a more homogeneous visual impression, and the transition from the functional element 5 to the intermediate layer 3c is less conspicuous. The “high flow PVB” can be used for all or even for only one or more of the intermediate layers 3a, 3b, 3c.

In another example, not illustrated here, the windshield and the functional element 5 with the barrier layer 4 substantially correspond to the embodiment of FIGS. 4A and 4B. The PDLC functional element 5 is, however, divided by horizontal isolation lines into, for example, six strip-like segments. The isolation lines have, for example, a width of 40 μm to 50 μm and are spaced 3.5 cm apart. They were introduced into the prefabricated multilayer film by laser. The isolation lines separate, in particular, the surface electrodes into strips isolated from one another, which have in each case a separate electrical connection. The segments can thus be switched independently of one another. The thinner the isolation lines, the less conspicuous they are. Even thinner isolation lines can be realized by etching.

The height of the darkened functional element 5 can be adjusted by the segmentation. Thus, depending on the position of the sun, the driver can darken the entire sun visor or even only part of it.

In a particularly convenient embodiment, the functional element 5 is controlled by a capacitive switch area arranged in the region of the functional element, wherein the driver determines the degree of darkening by the location at which he touches the pane. Alternatively, the functional element 5 can also be controlled by contactless methods, for example, by gesture recognition, or as a function of the state of the pupil or eyelid determined by a camera and suitable evaluation electronics.

Another aspect of the invention comprises a functional element (5) having electrically controllable optical properties, comprising

a stack sequence of at least:
a first carrier film (15),
an active layer (11), and
a second carrier film (14),
   wherein at least one exit surface (8) of the active layer (11) on at least one lateral surface (5.1, 5.2, 5.3, 5.4) of the functional element (5) is sealed, at least in sections, by at least one barrier layer (4).

Another aspect of the invention comprises a functional element (5) having electrically controllable optical properties, comprising

a stack sequence of at least:
a first carrier film (15),
an active layer (11), and
a second carrier film (14),
   wherein at least one exit surface (8) of the active layer (11) on at least one lateral surface (5.1, 5.2, 5.3, 5.4) of the functional element (5) is sealed, at least in sections, by at least one barrier layer (4), and the barrier layer (4) is formed single ply from one individual layer (4.1) or multi-ply from at least two individual layers (4.1,4.2) ausgebildet ist,
   wherein the individual layer (4.1) or at least one individual layer (4.1,4.2) of the barrier layer (4) contains or consists of the following materials:
   a) metal oxide-based, metal nitride-based, or metal oxynitride-based layers, wherein the metal is preferably silicon (Si), aluminum (Al), tantalum (Ta), or vanadium (V) or mixtures thereof, preferably sub-stoichiometric or stoichiometric silicon oxide layers,
   b) organometallic layers, preferably organosilicon layers of the type SiOxCy:H, preferably with x of 0.1 to 3 and y greater than 0.3,
   c) amorphous hydrogenated carbon (a-C:H), preferably amorphous hydrogenated nitrogen-doped carbon (a-C:N:H) or amorphous hydrogenated nitrogen- and silicon-doped carbon (a-C:N:Si:H)
   and/or
   d) other ceramic layers and/or polymer layers producible with vapor deposition methods, which layers reduce or substantially prevent the diffusion of plasticizers, preferably Parylene, polyvinylidene chloride (PVDC), ethylene vinyl alcohol copolymers (EVOP), or polyacrylates, and preferably the entire barrier layer (4) has over the exit surface (8) a thickness d of 10 nm to 5000 nm (nanometers), particularly preferably of 15 nm to 1000 nm, and most particularly preferably of 15 nm to 500 nm.

Advantageously, the exit surfaces (8) on all lateral surfaces (5.1, 5.2, 5.3, 5.4) are completely sealed by the barrier layer (4) or at least one of the lateral surfaces (5.1, 5.2, 5.3, 5.4) and preferably all lateral surfaces (5.1, 5.2, 5.3, 5.4) are completely sealed by the barrier layer (4) sealed.

Advantageously, the functional element (5) is a polymer dispersed liquid crystal (PDLC)-functional element.

### LIST OF REFERENCE CHARACTERS

1 outer pane
2 inner pane
3a first intermediate layer
3b second intermediate layer
3c third intermediate layer
4 barrier layer
4.1,4.2 individual layer of the barrier layer 4
5 functional element having electrically controllable optical properties
5.1,5.2,5.3,5.4 lateral surface of the functional element 5
6 tinted region of the first intermediate layer 3a
8 exit surface of the active layer 11
9 masking print
11 active layer of the functional element 5
12 surface electrode of the functional element 5
13 surface electrode of the functional element 5
14 carrier film
15 carrier film
20 vapor deposition system
21 vacuum chamber
22 high-frequency generator
23 adaptation electronics
24 cathode
25 anode
26 specimen holder
27 plasma zone
28 vacuum pump
30.1 first gas inlet
30.2 second gas inlet
31 gas outlet
100 composite pane
B central field of vision of the windshield
D upper edge of the windshield, roof edge
d thickness, material thickness
G₁ first process gas
G₂ second process gas
M lower edge of the windshield, engine edge
U overhang
X-X′ section line
Z, Z′,Z″ enlarged region

1. A composite pane having a functional element having electrically controllable optical properties, comprising:
a stack sequence of an outer pane, a first intermediate layer, a second intermediate layer, and an inner pane, wherein the intermediate layers contain at least one thermoplastic polymer film having at least one plasticizer, and
a functional element having electrically controllable optical properties is arranged, at least in sections, between the first intermediate layer and the second intermediate layer, and
the functional element is a polymer dispersed liquid crystal (PDLC) functional element,
wherein the functional element comprises a second stack sequence of at least
a first carrier film,
an active layer, and
a second carrier film, and
wherein at least one exit surface of the active layer is sealed, at least in sections, on at least one lateral surface of the functional element by at least one barrier layer,
the barrier layer is implemented such that the barrier layer substantially prevents the diffusion of plasticizer through the barrier layer, and
the barrier layer is produced by a vacuum-based thin-film deposition method.

2. The composite pane according to claim 1, wherein the vacuum-based thin-film deposition method is one of the following methods:
physical vapor deposition (PVD)
or
atomic layer deposition
and/or
chemical vapor deposition (CVD).

3. The composite pane according to claim 1, wherein the exit surfaces are completely sealed on all lateral surfaces by the barrier layer or wherein at least one of the lateral surfaces is completely sealed by the barrier layer.

4. The composite pane according to claim 1, wherein the barrier layer is implemented such that the barrier layer prevents the diffusion of plasticizer through the barrier layer to the same extent or to a greater extent than the diffusion of plasticizer through the carrier films.

5. The composite pane according to claim 1, wherein the barrier layer is implemented single-ply from one individual layer or multi-ply from at least two individual layers.

6. The composite pane according to claim 5, wherein the individual layer or at least one individual layer of the barrier layer contains or consists of the following materials:
a) metal oxide-based, metal nitride-based, or metal oxynitride-based layers,
b) organometallic layers,
c) amorphous hydrogenated carbon (a-C:H)
and/or
d) other ceramic layers and/or polymer layers producible with vapor deposition methods that reduce or substantially prevent the diffusion of plasticizers.

7. The composite pane according to claim 1, wherein the entire barrier layer has, over the exit surface, a thickness d of 10 nm to 5000 nm.

8. The composite pane according to claim 1, wherein the barrier layer is arranged directly on the lateral surface of the stack sequence of the functional element.

9. The composite pane according to claim 1, wherein the barrier layer consists at least of a first individual layer of an organosilicon compound of the type SiOₓC_{y}:H_{z} and a second silicon oxide-based individual layer.

10. The composite pane according to claim 1, wherein the intermediate layer contains at least 3 wt.-% of a plasticizer, and the plasticizer contains or consists of aliphatic diesters of tri- or tetraethylene glycol.

11. The composite pane according to claim 1, wherein the intermediate layer contains at least 60 wt.-% polyvinyl butyral (PVB).

12. A method for producing a functional element having electrically controllable optical properties, the method comprising:
a) providing a stack sequence of at least
a first carrier film,
an active layer, and
a second carrier film, and
b) sealing an exit surface of the active layer, at least in sections, on at least one lateral surface of the functional element by a barrier layer, wherein, the barrier layer is produced by a vacuum-based thin-film deposition method.

13. The method according to claim 12, further comprising the subsequent steps of
c) arranging an outer pane, a first intermediate layer, the functional element having electrically controllable optical properties, a second intermediate layer, and an inner pane one above another in this order, and
d) joining the outer pane and the inner pane by lamination, wherein an intermediate layer with an embedded functional element is formed from the first intermediate layer and the second intermediate layer.

14. A method comprising utilizing a composite pane according to claim 1 as a windshield or roof panel of a vehicle, wherein the functional element is used as a sun visor.

15. A method comprising utilizing a composite pane according to claim 1 as interior glazing or exterior glazing in a vehicle or a building, wherein the electrically controllable functional element is used as a sun screen or as a privacy screen.

16. The composite pane according to claim 2, wherein the
physical vapor deposition is thermal evaporation, electron beam evaporation, laser beam evaporation, ion assisted deposition (IAD), arc evaporation, or magnetron sputtering,
the atomic layer deposition is plasma enhanced atomic layer deposition (PEALD), and
the chemical vapor deposition (CVD) is plasma enhanced chemical vapor deposition (PECVD).

17. The composite pane according to claim 6, wherein
a) in the metal oxide-based, metal nitride-based, or metal oxynitride-based layers, the metal is silicon (Si), aluminum (Al), tantalum (Ta), or vanadium (V) or mixtures thereof,
b) the organometallic layers are organosilicon layers of the type SiOₓC_{y}:H, with x from 0.1 to 3 and y greater than 0.3,
c) the amorphous hydrogenated carbon (a-C:H) is amorphous hydrogenated nitrogen-doped carbon (a-C:N:H), or amorphous hydrogenated nitrogen- and silicon-doped carbon (a-C:N:Si:H),
and/or
d) the other ceramic layers and/or polymer layers are Parylene, polyvinylidene chloride (PVDC), ethylene vinyl alcohol copolymers (EVOP), or polyacrylates.

18. The composite pane according to claim 7, wherein the entire barrier layer has, over the exit surface, a thickness d of 15 nm to 500 nm.

19. The composite pane according to claim 8, wherein the barrier layer is arranged directly on the exit surface of the active layer and/or the lateral surfaces of the carrier films.

20. The composite pane according to claim 9, wherein the first individual layer is arranged directly on the stack sequence of the functional element, and the second individual layer is arranged directly on the first individual layer.
